(19) United States
(12) Patent Application Publication
(10) Pub. No.: US 2025/0118583 A1
(43) Pub. Date: Apr. 10, 2025

(54) COMMON RESOURCE SHARING AND MANAGEMENT FOR SUBSTRATE PROCESSING SYSTEMS

(71) Applicant: Applied Materials, Inc., Santa Clara, CA (US)

(72) Inventors: Kirankumar Neelasandra SAVANDAIAH, Bangalore (IN); Shankar KODLE, Bangalore (IN); Thomas BREZOCZKY, Los Gatos, CA (US)

(21) Appl. No.: 18/377,572

(22) Filed: Oct. 6, 2023

(51) Int. Cl. H01L 21/677; H01L 21/67

(52) U.S. Cl. CPC H01L 21/67727; H01L 21/67173; H01L 21/67709

(57) ABSTRACT

A method including processing substrates in two stations on separate processing lines. In the first station of the first processing line, the method may include: loading a first substrate, and delivering a resource for a first configurable period, during which the resource is locked out from the first station of the second processing line. In the first station of the second processing line, the method may include: loading a second substrate, and delivering a resource for a second configurable period, during which the resource is locked out from the first station of the first processing line.

### BACKGROUND

### Field

Embodiments of the present invention generally relate to a method of sharing resources among the various stations of a substrate processing system.

### Description of the Related Art

The fabrication of semiconductor structures and devices rely on a multitude of resources, such as a power supply, to be provided to a substrate processing system in precise quantity, quality, and timing. Power supplies used in substrate processing systems play a crucial role in ensuring the proper operation and control of various equipment and processes involved in substrate manufacturing and treatment. These power supplies are specifically designed to meet the unique requirements of substrate processing systems, which involve intricate and delicate processes such as thin film deposition, etching, and surface treatment.

Power supplies used in substrate processing systems often feature advanced voltage and current regulation capabilities to maintain the desired process parameters. The power supplies must provide a highly stable and clean power output, minimizing variations and fluctuations that could adversely affect the quality and consistency of the processed substrates. Additionally, these power supplies may incorporate specialized safety features to protect against electrical hazards and ensure the reliability of the system.

Furthermore, power supplies for substrate processing systems are designed to support specific process requirements. The power supplies may offer programmable voltage and current settings, enabling fine-tuning of process parameters to achieve optimal results. These power supplies often integrate advanced control features and interfaces, allowing seamless integration with other equipment and enabling precise synchronization of power delivery with process steps.

All of these features and considerations make power supplies for substrate processing systems very complex and expensive, especially when considering that many of the power supplies remain idle for significant periods of time. Accordingly, there is a need in the art for a more efficient implementation and utilization of power supply resources.

### SUMMARY

Embodiments described herein generally relate to resource sharing among the various processing stations of a substrate processing system. More particularly, embodiments described herein provide methods for more efficient resource utilization of power delivery, gas delivery, vacuum pump or other shared resources.

One general aspect includes a method of substrate processing. The method also includes processing a first substrate within a first station within a first substrate processing line of a substrate processing system, where the first substrate processing line may include a plurality of stations that may include at least the first station, and processing the first substrate may include: loading the first substrate into a processing area of the first station of the first substrate processing line, and delivering a first resource from a first common resource to a component within the first station of the first substrate processing line for a first configurable period of time. The method also includes locking out the first resource from providing the first common resource to a component within a first station of a second substrate processing line for the first configurable period of time. The method also includes unloading the first substrate from the processing area of the first station of the first substrate processing line after the first configurable period of time has elapsed. The method also includes processing a second substrate within the first station within the second substrate processing line of the substrate processing system, where the second substrate processing line may include a plurality of stations that may include at least the first station, and processing the second substrate may include: loading the second substrate into a processing area of the first station of the second substrate processing line, and delivering the first resource from the first common resource to the component within the first station of the second substrate processing line for a second configurable period of time. The method also includes locking out the first resource from providing the first common resource to the component within the first station of the first substrate processing line for the second configurable period of time. The method also includes unloading the second substrate from the processing area of the first station of the second substrate processing line. Other embodiments of this aspect include corresponding computer systems, apparatus, and computer programs recorded on one or more computer storage devices, each configured to perform the actions of the methods.

One general aspect includes a method of substrate processing. The method also includes processing a first substrate within a first station within a first substrate processing line of a substrate processing system, where the first substrate processing line may include a plurality of stations that may include at least the first station, and processing the first substrate may include: loading the first substrate into a processing area of the first station of the first substrate processing line, where loading the first substrate into the processing area of the first station of the first substrate processing line occurs before a third configurable period of time, and a fourth configurable period of time, have elapsed, delivering a first resource from a first common resource to a component within the first station of the first substrate processing line for a first configurable period of time, where the first resource from the first common resource is a power resource from a common power resource, and delivering a second resource from a second common resource to a component within the first station of the first substrate processing line for a second configurable period of time, where the second resource from the second common resource is a vacuum resource from a common vacuum resource. The method also includes locking out the first resource from providing the first common resource to a component within a first station of a second substrate processing line for the first configurable period of time. The method also includes locking out the second resource from providing the second common resource to a component within a first station of a second substrate processing line for the second configurable period of time. The method also includes unloading the first substrate from the processing area of the first station of the first substrate processing line after the first configurable period of time, and the second configurable period of time, have elapsed. The method also includes processing a second substrate within the first station within the second substrate processing line of the substrate processing system, where the second substrate processing line may include a plurality of stations that may include at least the first station, and processing the second substrate may include: loading the second substrate into a processing area of the first station of the second substrate processing line, where loading the second substrate into the processing area of the first station of the second substrate processing line occurs before the first configurable period of time, and the second configurable period of time, have elapsed, delivering the first resource from the first common resource to the component within the first station of the second substrate processing line for the third configurable period of time, and delivering the second resource from the second common resource to the component within the first station of the second substrate processing line for the fourth configurable period of time. The method also includes locking out the first resource from providing the first common resource to the component within the first station of the first substrate processing line for the third configurable period of time. The method also includes locking out the second resource from providing the second common resource to the component within the first station of the first substrate processing line for the fourth configurable period of time. The method also includes unloading the second substrate from the processing area of the first station of the second substrate processing line after the third configurable period of time, and the fourth configurable period of time, have elapsed. Other embodiments of this aspect include corresponding computer systems, apparatus, and computer programs recorded on one or more computer storage devices, each configured to perform the actions of the methods.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a top schematic view of a substrate processing system, according to one embodiment.

FIG. 2 is a top schematic view of a conventional substrate processing system power supply layout.

FIG. 3 is a top schematic view of a substrate processing system power supply layout according to one embodiment.

FIG. 4 is a schematic of a substrate power supply layout according to one embodiment.

FIG. 5 is a top schematic view of a substrate processing system resource supply layout according to one embodiment.

FIG. 6 is a schematic of a substrate resource supply layout according to one embodiment.

FIG. 7 is a flow diagram of a method of sharing a power supply in a substrate processing system according to one embodiment.

FIGS. 8A-8D illustrate the movement of a substrate during a substrate processing sequence that can be performed in the substrate processing system illustrated in FIG. 1, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The fabrication of semiconductor devices in semiconductor processing tools requires the use of a multitude of resources to perform the semiconductor device fabrication steps in various substrate processing chambers positioned within a substrate process system. The multitude of different resources include dedicated power supplies, gas sources, evacuation equipment (e.g., vacuum pumps) and heat delivery and removal components that are typically assigned to each processing chamber within a substrate processing system. Typically, power supplies used in semiconductor substrate processing systems often feature advanced voltage and current regulation capabilities to maintain the desired process parameters, which makes these types of power supplies very expensive. For example, the power supplies must provide a highly stable and clean power output, minimizing variations and fluctuations that could adversely affect the quality and consistency of the processed substrates. Additionally, these power supplies may incorporate specialized safety features to protect against electrical hazards and ensure the reliability of the system. Furthermore, the resources, such as power supplies are designed to support specific process requirements. The power supplies may offer programmable voltage and current settings, enabling fine-tuning of process parameters to achieve optimal results. These power supplies often integrate advanced control features and interfaces, allowing seamless integration with other equipment and enabling precise synchronization of power delivery with process steps. However, as noted above, the use of a multitude of different resources within a substrate processing system makes the overall system complex and expensive to manufacture, especially when considering that many of the different resources remain idle for significant periods of time and thus are under-utilized.

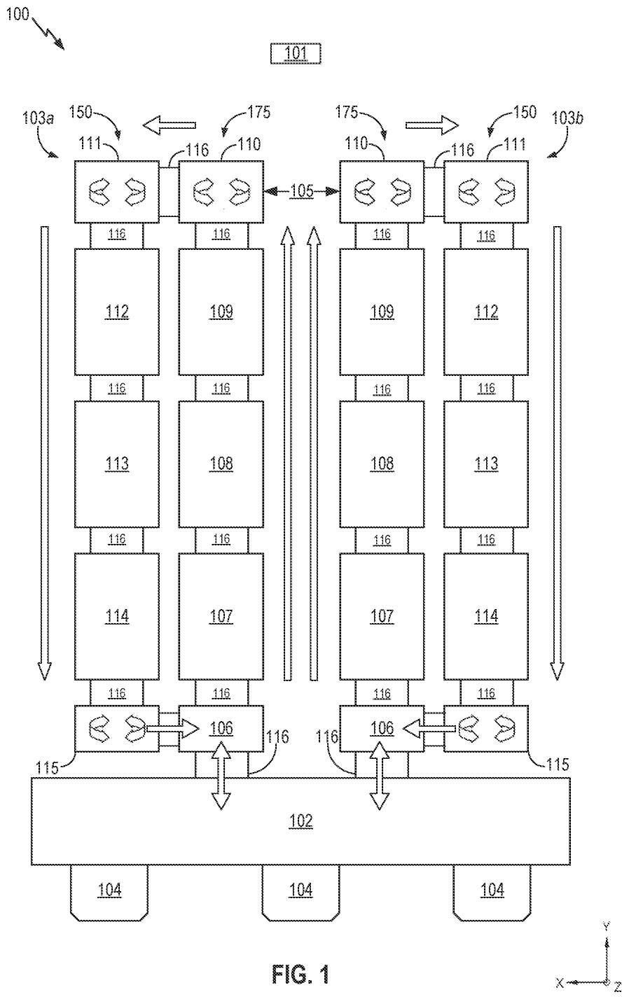

FIG. 1 illustrates a schematic of a substrate processing system 100 that can be used to process a semiconductor substrate in a plurality of process chambers. The substrate processing system 100 includes a controller 101, at least one processing line 103, and a factory interface 102.

As shown, first processing line 103a, and second processing line 103b, collectively referred to as processing line(s) 103, each include a plurality of stations, such as stations 106-115. In some embodiments, each of the processing lines 103 includes a magnetic transportation system (not shown) formed from the individual magnetic levitation assemblies that convey a substrate (not shown) disposed on a substrate carrier (not shown) through the stations 106-115 of the processing line 103. Each of the processing lines 103 is independent of the others. As shown, the processing lines 103 are physically separated from one another by a gap 105. The gap 105 may be sized such that a technician may walk between each of the processing lines 103 to service one or more stations within each of the processing lines 103.

Each processing line 103 may include a plurality of slit valves 116 to selectively isolate each station. The slit valves are selectively opened and closed to allow a clear path for the travel of the substrate carrier (not shown) and to selectively isolate the stations 106-115 from one another and to facilitate the pressurization or depressurization of a station.

The substrate processing system 100 is used to process multiple substrates in each processing line 103 to produce a desired fabricated substrate. For example, the substrate processing system 100 may include a plurality of stations that are configured to perform a physical vapor deposition (PVD) process. For example, the first station 106 is a first load lock, the second station 107 is a degas station, the third station 108 is a pre-clean station, the fourth station 109 is a second pre-clean station, the fifth station 110 is a routing station, the sixth station 111 is a routing station, the seventh station 112 is a PVD tantalum nitride deposition station, the eighth station 113 is a PVD copper deposition station, the ninth station 114 is a second PVD copper deposition station, and the tenth station 115 is a routing station that also serves as a buffer station. The substrate is transferred and processed within each process station 107-109 and 112-114.

Each processing line 103 of the substrate processing system 100 may include a first common resource to deliver a first resource, for example, at least one of a common power resource (not shown) to deliver AC or DC power to a station component, a common gas system (not shown) to deliver a gas resource from a common gas resource from a common gas resource or remove a gas from a station, such as provide a gas to achieve an gas pressure greater than about 760 Torr within a station or remove a gas to achieve a vacuum pressure from about 10⁻⁹ Torr to about 760 Torr within a station, or a heat exchanging and heat control system, or any combination thereof. In some embodiments there may be a first common resource, a second common resource, a third common resource, . . . , and an N^{th} common resource, are used to deliver a first resource, a second resource, a third resource, . . . ,and an N^{th} resource to the various stations of each processing line 103 of the substrate processing system 100. In other embodiments, the first common resource, the second common resource, the third common resource, . . . , and the N^{th} common resource, to deliver the first resource, the second resource, a third resource, . . . ,and the N^{th} resource may be a single common resource.

The at least one gas system may include at least one vacuum pump (not shown) to generate a vacuum pressure within the stations 106-115. The vacuum pump (not shown) may be a turbopump, cryopump, roughing pump or other useful device that is able to maintain a desired vacuum pressure within at least process stations 107-109, and 112-114, load lock of the first station 106, routing stations 110-111, and 115. The magnitude of a vacuum pressure within each station may increase from the first station to the last station within a substrate transfer sequence. For example, the magnitude of the vacuum pressure in the ninth station 114 (e.g., 10⁻⁷ Torr base pressure) may exceed the magnitude of a vacuum pressure in the other stations, such as first station 106 (e.g., 10⁻³ Torr base pressure).

In some embodiments, the first station 106 (e.g., load lock) includes a magnetic levitation assembly (not shown) that includes an array of magnetic levitation actuators (not shown) that are configured to levitate and impart a translational motion to a carrier (not shown) that is configured to support a substrate during a substrate transferring process. The second station 107, the third station 108, fourth station 109, seventh station 112, eighth station 113, and ninth station 114 (e.g., process stations) are also similarly configured.

FIG. 1 includes an X-Y-Z coordinate system to show the direction of travel of the carrier and substrate through the substrate processing system 100. The arrows illustrate the direction that one or more carriers circulate within the processing line 103. The carrier (not shown) receives a substrate entering the first station 106 in the Y-direction from a front opening unified pod (FOUP) 104 of the factory interface 102. The carrier (not shown) is then conveyed to the second station 107 in the Y-direction. The first station 106 also receives the carrier (not shown) from the tenth station 115 in the X-direction. After the carrier (not shown) is conveyed into the second station 107, the carrier (not shown) is conveyed to the fifth station 110 through the third station 108, and the fourth station 109, in the Y-direction. The carrier (not shown) is then conveyed from the fifth station 110 to the sixth station 111 in the negative X-direction. The carrier (not shown) is then conveyed from the sixth station 111 to the tenth station 115 in the negative Y-direction through the process stations 112-114 to the tenth station 115. The carrier (not shown) is then conveyed in the X-direction and back into the first station 106. The now processed substrate (not shown) is transferred to a FOUP 104 of the factory interface 102. Another substrate may be placed onto a carrier positioned in the first station 106 for the processing operation as described above.

In some embodiments of substrate processing system 100, the processing line 103 has a non-deposition portion 175 and a deposition portion 150. The non-deposition portion 175 may include a linear arrangement of stations, such as the first station 106, the second station 107, the third station 108, the fourth station 109, and the fifth station 110, that do not subject the substrate to a process that deposits a layer on the substrate. After the substrate passes through the non-deposition portion 175, the substrate is conveyed into the deposition portion 150 that may be a linear arrangement of stations, such as the sixth station 111, the seventh station 112, the eighth station 113, the ninth station 114, and the tenth station 115 that includes at least one station that deposits at least one layer the substrate. For example, the non-deposition portion 175 includes the first station 106 that is a first load lock, the second station 107 that is a degas station, the third station 108 that is a pre-clean station, the fourth station 109 that is a second pre-clean station, and the fifth station 110 that is a routing station. The deposition portion 150 includes the sixth station 111 that is a routing station, the seventh station 112 that is a PVD tantalum nitride deposition station, the eighth station 113 that is a PVD copper deposition station, the ninth station 114 that is a second copper deposition station, and the tenth station 115 that is a routing station that also serves as a buffer station.

In some embodiments, the stations of the non-deposition portion 175, such as the second station 107, the third station 108, or the fourth station 109, may each respectively be a degas station, pre-clean station, pre-heating station, annealing station, cool down station, or any other suitable substrate processing station. In some embodiments, the stations of the deposition portion 150, such as the seventh station 112, the eighth station 113, and the ninth station 114, may each respectively be a tantalum nitride deposition station, copper deposition station, etching station, or any deposition station that deposits at least one layer on the substrate. In the example provided in FIG. 1, the stations of the deposition portion 150 utilize PVD. In other embodiments, one or more of the stations of the deposition portion 150 of the substrate processing system may utilize PVD, chemical vapor deposition (CVD), atomic layer deposition (ALD), or any combination thereof.

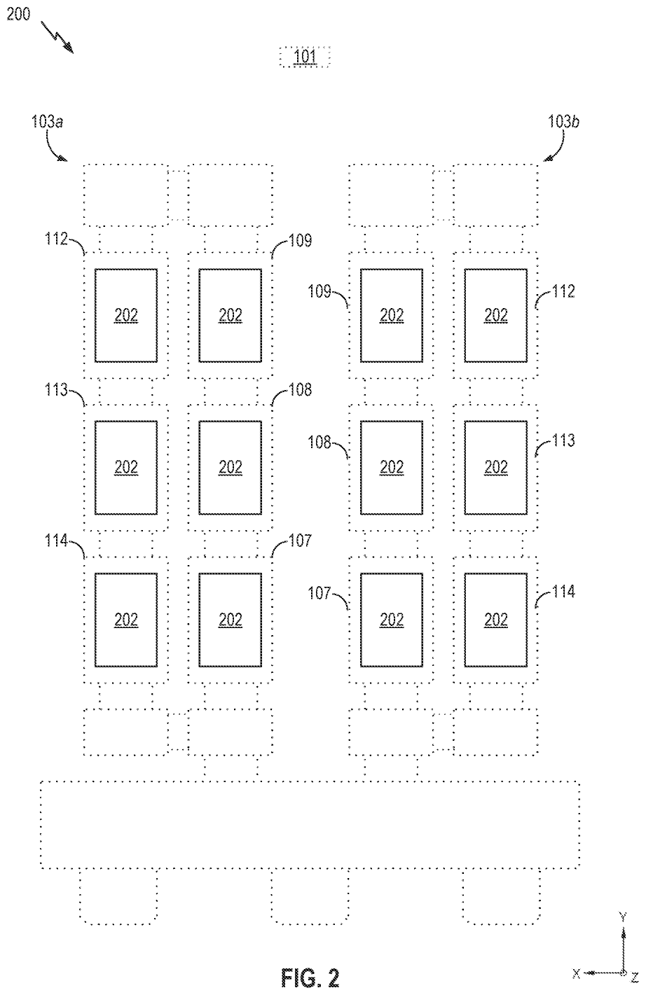

FIG. 2 is a top schematic view of a substrate processing system power supply layout 200. Recalling FIG. 1, each of the ten stations 105-115 of each of the processing lines 103, magnetic transportation system (not shown), and other ancillary equipment require electrical power, and other resources, in order to perform their associated functions. The substrate processing system power supply layout 200 illustrated in FIG. 2 shows a conventional configuration where the second station 107, the third station 108, the fourth station 109, the seventh station 112, the eighth station 113, and the ninth station 114 each include a power supply 202. The power supply 202 may be of any suitable type, such as a linear power supply, switching power supply, uninterruptable power supply, alternating current (AC) power supply, direct current (DC) power supply, programmable power supply, high voltage power supply, or radio frequency (RF) power supply, according to the needs of the connected station, or device

The power supply 202 includes at least a power input and a power output. The power supply 202 may include a transformer, DC-to-DC converter, rectifier, voltage regulator, and/or filter. The power supply 202 power input may be configured accept an alternating current (AC) input or direct current (DC) input. The power supply 202 power output may be configured to provide an AC or DC source. The power supply 202 may include a transformer to accept an AC input and which may then be stepped up or down to match the voltage level required. The power supply 202 may include a DC-to-DC converter such as a buck converter, boost converter, or buck-boost converter to step up or step down a DC input to match the voltage required. The power supply 202 may include a rectifier, of suitable topology, to accept an AC input and convert the AC input to a DC output. The power supply 202 may include a voltage regulator employed to maintain a constant output voltage despite fluctuations in the input voltage or variations in the load. The voltage regulator may be of any suitable topology, for example a liner regulator or switching regulator. In some embodiments, the power supply 202 may include a filter configured to smooth out or reduce unwanted variations, harmonics, or noise in the output voltage or current. In some embodiments, the filter may include a capacitive filter, inductive filter, or inductive-capacitive filter of suitable topology. In some embodiments, the filter may be an active filter, passive filter, digital filter, or a combination thereof. In some embodiments, the power supply 202 may include various protection mechanisms such as overcurrent protection, overvoltage protection, power conditioning, and/or short circuit protection to safeguard both the power supply and the connected station, or device.

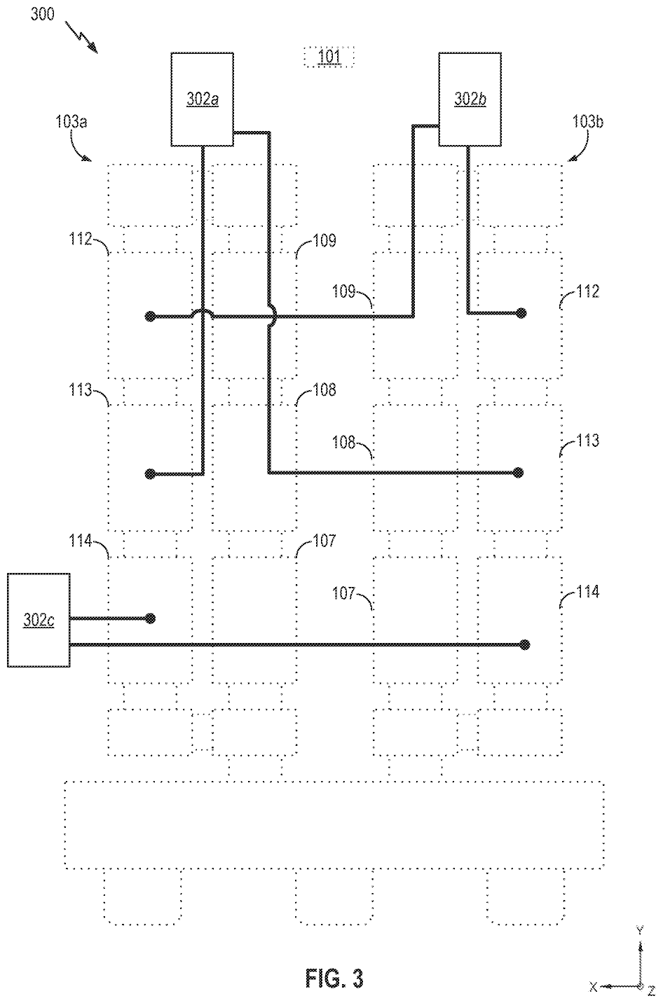

FIG. 3 is a schematic view of a substrate processing system power supply layout 300 according to one embodiment. The substrate processing system power supply layout 300 is adapted to support components within at least one of the second station 107, the third station 108, the fourth station 109, the seventh station 112, the eighth station 113, and the ninth station 114 of first processing line 103a. The substrate processing system power supply layout 300 is also adapted to support components within at least one of the second station 107, the third station 108, the fourth station 109, the seventh station 112, the eighth station 113, and the ninth station 114 of second processing line 103b.

FIG. 3 includes three power supplies, power supply 302a, power supply 302b, and power supply 302c, which are collectively referred to as power supplies 302. The power supplies 302 may be of any suitable type, such as a linear power supply, switching power supply, uninterruptable power supply, alternating current (AC) power supply, direct current (DC) power supply, programmable power supply, high voltage power supply, or radio frequency (RF) power supply, according to the needs of the connected stations, or devices.

The power supplies 302 include at least one power input (not shown) and two or more power outputs that are connected to a component in two or more separate substrate processing stations. The power supplies 302 may include a transformer, DC-to-DC converter, rectifier, voltage regulator, and/or filter. The power supplies 302 power input may be configured accept an alternating current (AC) input or direct current (DC) input. The power supplies 302 power output may be configured to provide an AC or DC source. The power supplies 302 may include a transformer to accept an AC input and which may then be stepped up or down to match the voltage level required. The power supplies 302 may include a DC-to-DC converter such as a buck converter, boost converter, or buck-boost converter to step up or step down a DC input to match the voltage required. The power supplies 302 may include a rectifier, of suitable topology, to accept an AC input and convert the AC input to a DC output. The power supplies 302 may include a voltage regulator employed to maintain a constant output voltage despite fluctuations in the input voltage or variations in the load. The voltage regulator may be of any suitable topology, for example a liner regulator or switching regulator. In some embodiments, the power supplies 302 may include a filter configured to smooth out or reduce unwanted variations, harmonics, or noise in the output voltage or current. In some embodiments, the filter may include a capacitive filter, inductive filter, or inductive-capacitive filter of suitable topology. In some embodiments, the filter may be an active filter, passive filter, digital filter, or a combination thereof. In some embodiments, the power supplies 302 may include various protection mechanisms such as overcurrent protection, overvoltage protection, power conditioning, and/or short circuit protection to safeguard both the power supply and the connected station, or device.

In this embodiment, power supply 302a is in communication with the seventh station 112 of first processing line 103a, and is also in communication with the seventh station 112 of second processing line 103b. The power supply 302a is thus configured to provide an AC, DC or RF voltage or current to one or more components in either of the seventh stations 112 in the first processing lines 103a or the second processing lines 103b. Power supply 302b is in communication with the eighth station 113 of first processing line 103a, and is also in communication with the eighth station 113 of second processing line 103b. The power supply 302b is thus configured to provide an AC, DC or RF voltage or current to one or more components in either of the eighth stations 113 in the first processing lines 103a or the second processing lines 103b. Power supply 302c is in communication with the ninth station 114 of first processing line 103a. Power supply 302c is in communication with the ninth station 114 of second processing line 103b. The power supply 302c is thus configured to provide an AC, DC or RF voltage or current to one or more components in either of the ninth stations 114 in the first processing lines 103a or the second processing lines 103b.

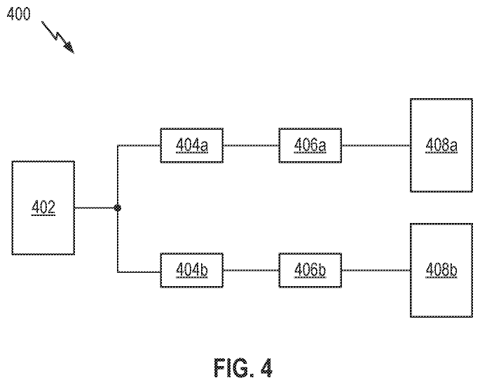

FIG. 4 is a schematic of a substrate power supply layout 400 according to one embodiment. According to one embodiment, the substrate power supply layout 400 includes a common power resource 402, two load switches 404, such as load switch 404a and load switch 404b, two auxiliary modules 406, such as auxiliary module 406a and auxiliary module 406b, and two connected devices 408, such as connected device 408a and connected device 408b.

The common power resource 402 is in communication to two connected devices 408 via two paths. The first of the two paths including load switch 404a, auxiliary module 406a, and connected device 408a, and the second of the two paths including load switch 404b, auxiliary module 406b, and connected device 408b.

In this embodiment the connected devices 408, such as connected device 408a and connected device 408b, are the same type of device. In one example, connected device 408a and connected device 408b are PVD targets disposed in two separate substrate processing stations. As an example, the common power resource 402 may be in communication with a PVD target disposed in the seventh station 112 of first processing line 103a and also in communication with a PVD target disposed in the seventh station 112 of second processing line 103b shown in FIG. 3. In this example, the PVD targets are used to deposit a material layer on a surface of a substrate disposed within the seventh station 112 within each processing line due to bias applied by the common power resource 402 to the PVD targets at separate time intervals to cause sputtering of the target surface. The common power resource 402 may be of any suitable type, such as a linear power supply, switching power supply, uninterruptable power supply, alternating current (AC) power supply, direct current (DC) power supply, programmable power supply, high voltage power supply, or radio frequency (RF) power supply, according to the needs of the connected device. In this example, DC power may be provided from the common power resource 402 to one of the targets within a seventh station 112 during a sputtering process which is greater than 10 kilowatts (KW), such as between 10 KW and 50 kW.

In some other examples, connected device 408a and connected device 408b are resistive heating elements used to heat a surface of a substrate support, bake-out lamps used to provide heat to an internal region of a station, or other similar processing devices commonly used in two or more separate substrate processing stations. In one example, the common power resource 402 is an RF power supply and the connected device 408a and connected device 408b are RF matches that are connected to one or more electrodes or coils within separate substrate processing stations.

In general, the common power resource 402 includes at least a power input (not shown) and one or more power outputs that are connected to a component in two or more separate substrate processing stations. The common power resource 402 may include a transformer, DC-to-DC converter, rectifier, voltage regulator, and/or filter. The common power resource 402 power input may be configured accept an alternating current (AC) input or direct current (DC) input. The common power resource 402 power output may be configured to provide an AC or DC source. The common power resource 402 may include a transformer to accept an AC input and which may then be stepped up or down to match the voltage level required. The common power resource 402 may include a DC-to-DC converter such as a buck converter, boost converter, or buck-boost converter to step up or step down a DC input to match the voltage required. The common power resource 402 may include a rectifier, of suitable topology, to accept an AC input and convert the AC input to a DC output. The common power resource 402 may include a voltage regulator employed to maintain a constant output voltage despite fluctuations in the input voltage or variations in the load. The voltage regulator may be of any suitable topology, for example a liner regulator or switching regulator. In some embodiments, the common power resource 402 may include a filter configured to smooth out or reduce unwanted variations, harmonics, or noise in the output voltage or current. In some embodiments, the filter may include a capacitive filter, inductive filter, or inductive-capacitive filter of suitable topology. In some embodiments, the filter may be an active filter, passive filter, digital filter, or a combination thereof. In some embodiments, the common power resource 402 may include various protection mechanisms such as overcurrent protection, overvoltage protection, power conditioning, and/or short circuit protection to safeguard both the power supply and the connected devices 408.

Each of the load switches 404, such as load switch 404a and load switch 404b, include a switching mechanism. The switching mechanism may be mechanical, electromechanical, solid-state, or a combination thereof. In one example, each load switch 404a, 404b is a single-pole single-throw (SPST) mechanical switch or MOSFET power switch. In another example, a load switch 404 is a single-pole double-throw (SPDT) switch. In another example, a load switch 404 is a double-pole double-throw (DPDT) switch. Each load switch 404 may include a suppression circuit, for example, a flyback diode. In this embodiment, each load switch 404 provides power, or halts power to, one connected device 408. In other embodiments, each load switch 404 may provide power, or halt power to, two or more connected devices 408.

Each of the load switches 404 may be opened or closed through a control interface. The control interface may be manually operated through physical interaction, or remotely controlled using electronic signals or automation systems, such as controller 101. Remote control options include digital control signals, analog control signals, or wireless communication protocols. In some embodiments, the load switches 404 supply power to each of the connected devices 408, alternating the supply of electrical power from common power resource 402, via load switch 404a, and then through auxiliary module 406a to connected device 408a for a first period of time, and then, according to a configurable duty cycle, or when indicated by a controller 101, alternating the supply of electrical power from common power resource 402, via load switch 404b, and then through auxiliary module 406b to connected device 408b for a second period of time. By supplying electrical power to only one of the connected devices 408 when needed, one common power resource 402 may be more efficiently used, due to the reduced amount of idle time than prior conventional implementations requiring two or more power sources, which also traditionally increased system complexity and system cost. However, due to the use of the substrate power supply layout 400 configuration disclosed herein, the system throughput will often be reduced, as a trade-off for the reduced system cost and complexity, due to the time required for the shared resource to become available for use in a second processing station once a process has started in first processing station.

Each connection from each load switch 404 to the connected device 408 may first pass through an optional auxiliary module 406. The optional auxiliary module 406 may include a voltage regulator employed to maintain a constant output voltage despite fluctuations in the input voltage or variations in the load. The voltage regulator may be of any suitable topology, for example a liner regulator or switching regulator. In some embodiments, the auxiliary module 406 may include a filter configured to smooth out or reduce unwanted variations, harmonics, or noise in the output voltage or current. In some embodiments, the filter may include a capacitive filter, inductive filter, or inductive-capacitive filter of suitable topology. In some embodiments, the filter may be an active filter, passive filter, digital filter, or a combination thereof. In some embodiments, the auxiliary module 406 may include various protection mechanisms such as overcurrent protection, overvoltage protection, transient suppression, power conditioning, and/or short circuit protection to safeguard both the power supply and the connected devices 408. In other embodiments, no auxiliary module 406 may be present, or required.

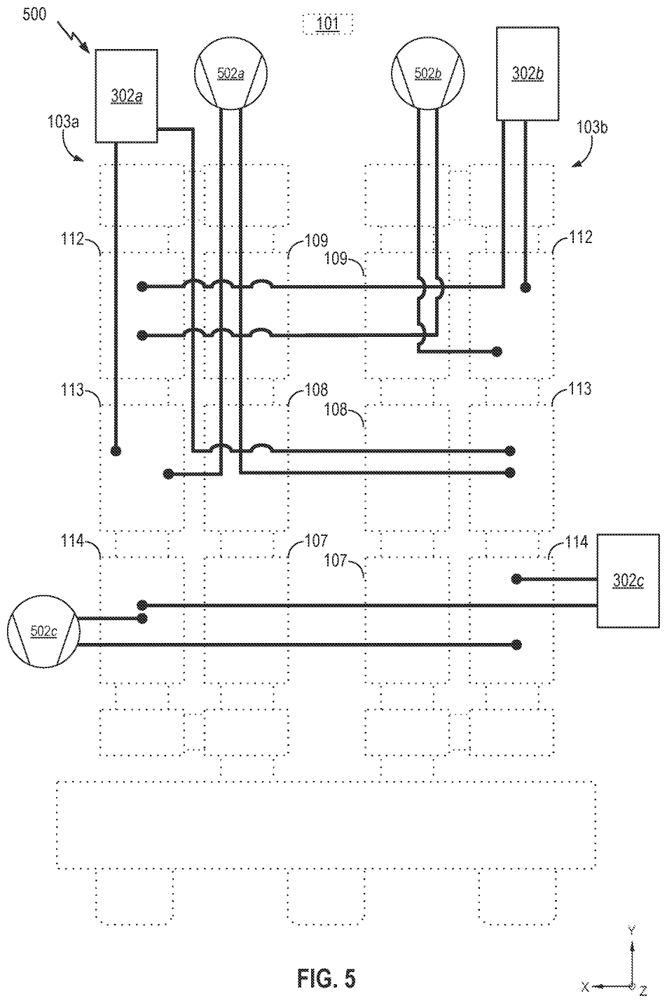

FIG. 5 is a top schematic view of a substrate processing system resource supply 500 according to one embodiment. In one embodiment, the shared resource is a vacuum pressure provided by a vacuum system having at least one vacuum pump, and a power resource provided by at least one power supply.

The substrate processing system resource supply 500 is adapted to support components within at least one of the second station 107, the third station 108, the fourth station 109, the seventh station 112, the eighth station 113, and the ninth station 114 of first processing line 103a. The substrate processing system resource supply 500 is adapted to also support and/or control the pressure within at least one of the second station 107, the third station 108, the fourth station 109, the seventh station 112, the eighth station 113, and the ninth station 114 of second processing line 103b.

FIG. 5 includes three vacuum pumps, vacuum pump 502a, vacuum pump 502b, and vacuum pump 502c (collectively referred to as vacuum pumps 502) create and maintain a controlled environment at a low pressure and low levels of contaminants to facilitate the precise deposition, etching, and other processes involved substrate processing. In other embodiments, there may be a single vacuum pump 502. The vacuum pumps 502 may be of any suitable type, such as rotary vane pumps, turbomolecular pumps, cryogenic pumps, or dry pumps, depending on the specific requirements of the process and the desired vacuum level.

FIG. 5 includes three power supplies, power supply 302a, power supply 302b, and power supply 302c, which are collectively referred to as power supplies 302. In other embodiments, there may be a power supply 302.

In this embodiment, vacuum pump 502a is in communication with the seventh station 112 of first processing line 103a, and is also in communication with the seventh station 112 of second processing line 103b. Vacuum pump 502b is in communication with the eighth station 113 of first processing line 103a, and is also in communication with the eighth station 113 of second processing line 103b. Vacuum pump 502c is in communication with the ninth station 114 of first processing line 103a, and is also in communication with the ninth station 114 of second processing line 103b. In other embodiments, there may be as few as one vacuum pump, or as many as one vacuum pump per station.

In this embodiment, power supply 302a is in communication with the seventh station 112 of first processing line 103a, and is also in communication with the seventh station 112 of second processing line 103b. The power supply 302a is thus configured to provide an AC, DC or RF voltage or current to one or more components in either of the seventh stations 112 in the first processing lines 103a or the second processing lines 103b. Power supply 302b is in communication with the eighth station 113 of first processing line 103a, and is also in communication with the eighth station 113 of second processing line 103b. The power supply 302b is thus configured to provide an AC, DC or RF voltage or current to one or more components in either of the eighth stations 113 in the first processing lines 103a or the second processing lines 103b. Power supply 302c is in communication with the ninth station 114 of first processing line 103a. Power supply 302c is in communication with the ninth station 114 of second processing line 103b. The power supply 302c is thus configured to provide an AC, DC or RF voltage or current to one or more components in either of the ninth stations 114 in the first processing lines 103a or the second processing lines 103b.

In other embodiments, the shared substrate processing system resource supply 500 may include, a gas system (not shown) to deliver a gas resource from a common gas resource or remove a gas from a station, such as provide a gas to achieve an gas pressure greater than about 760 Torr within a station or remove a gas to achieve a vacuum pressure from about 10⁻⁹ Torr to about 760 Torr within a station, or a heat exchanging and heat control system, or any combination thereof.

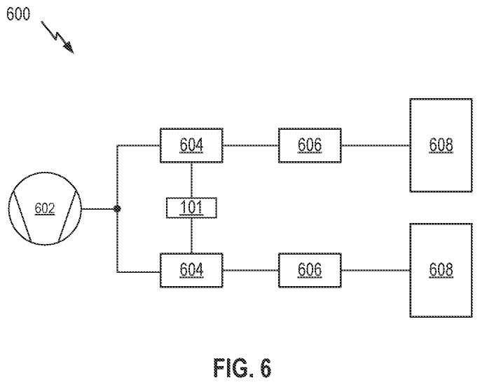

FIG. 6 is a schematic of a substrate resource supply 600 according to one embodiment. According to one embodiment, the substrate resource supply 600 includes a vacuum pump 602, in communication with two valves 604, each of the respective valves 604 in communication with optional support equipment 606, each support equipment 606 in communication a connected device 608.

The vacuum pump 602 is in communication to two connected devices 608 via two paths, each path including a valve 604 and optional support equipment 606. In this embodiment, the vacuum pump 602 is in communication with two of the same connected devices 608. In one example, each of the connected devices 608 include a processing station. As an example, the vacuum pump 602 may be in communication with the seventh station 112 of first processing line 103a and also in communication with the seventh station 112 of second processing line 103b shown in FIG. 5. In other embodiments the vacuum pump 602 is in communication with different connected devices 608.

The vacuum pump 602 may be of any suitable type, such as rotary vane pumps, turbomolecular pumps, cryogenic pumps, or dry pumps, depending on the specific requirements of the process and the desired vacuum level.

Each connection from each valve 604 to the connected device 608 first passes through optional support equipment 606. The valve 604 may be of any suitable type such as a gate valve, butterfly valve, ball valve, needle valve, angle valve, poppet valve, diaphragm valve, solenoid valve, or vacuum break valve depending on factors such as the specific application, pressure range, flow rate, material compatibility, and desired level of sealing. The valve 604 may be operated manually, mechanically, electronically, electromechanically, or by a pilot source. The optional support equipment 606 may include pressure measurement and control features, additional vacuum valves, gas purification systems, accumulators, vacuum interlocks, and safety systems. In other embodiments, no support equipment 606 may be present, or required.

### Processing Sequence Example

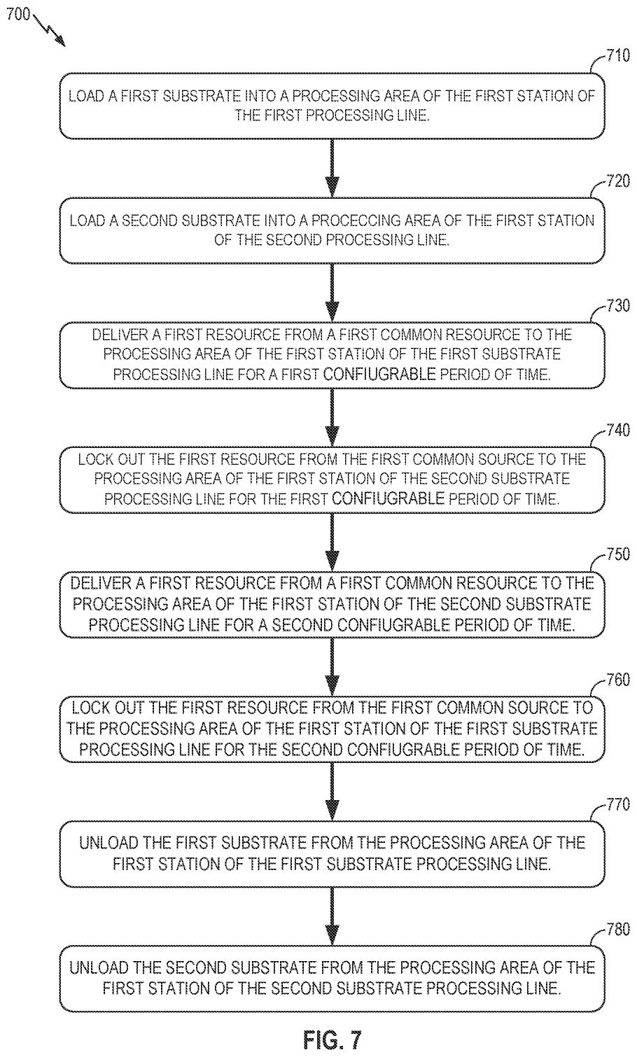

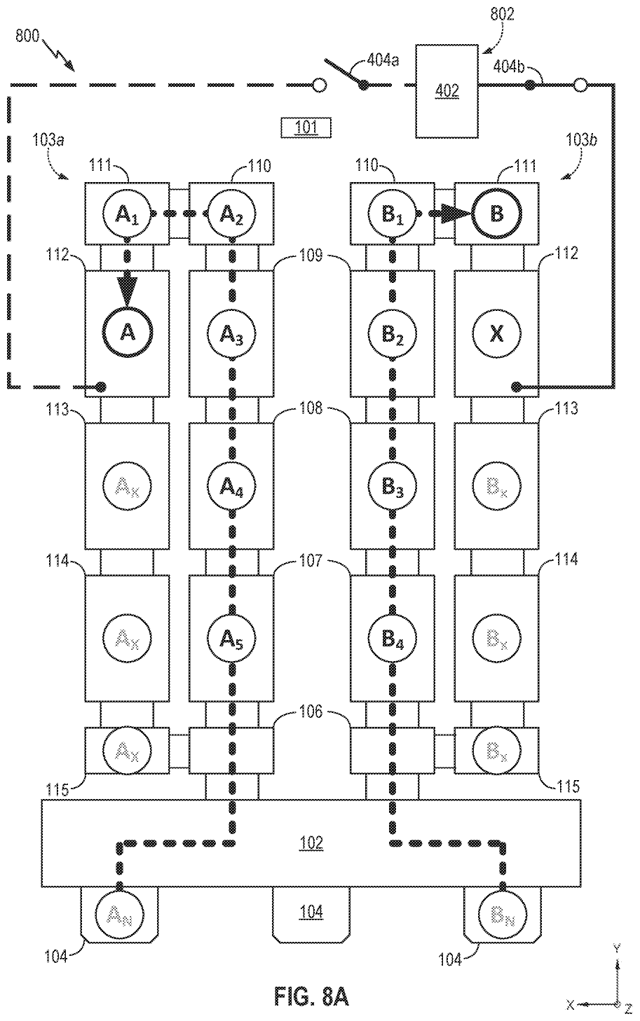

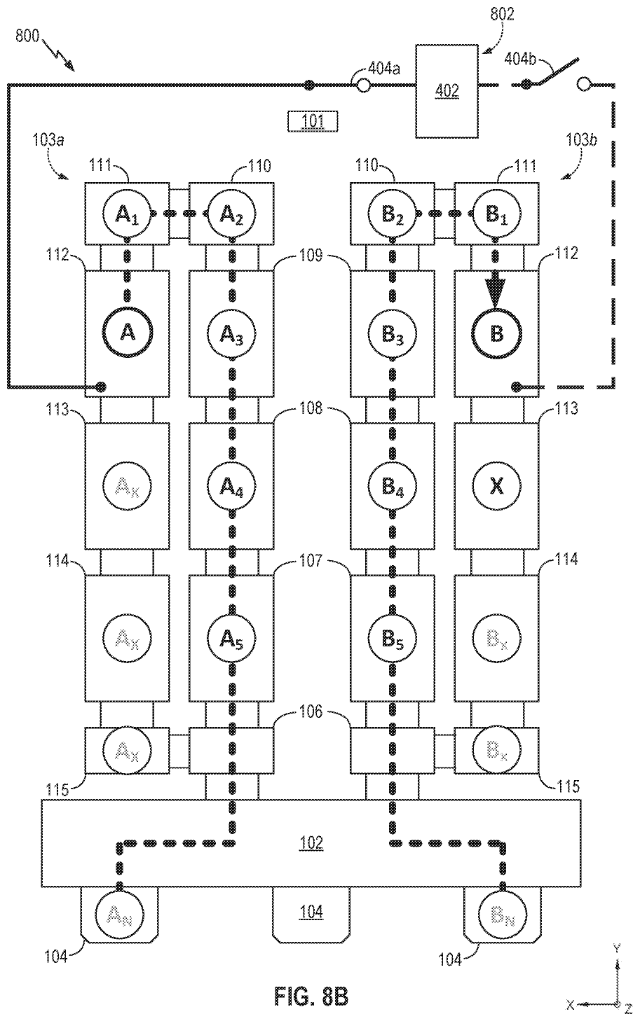

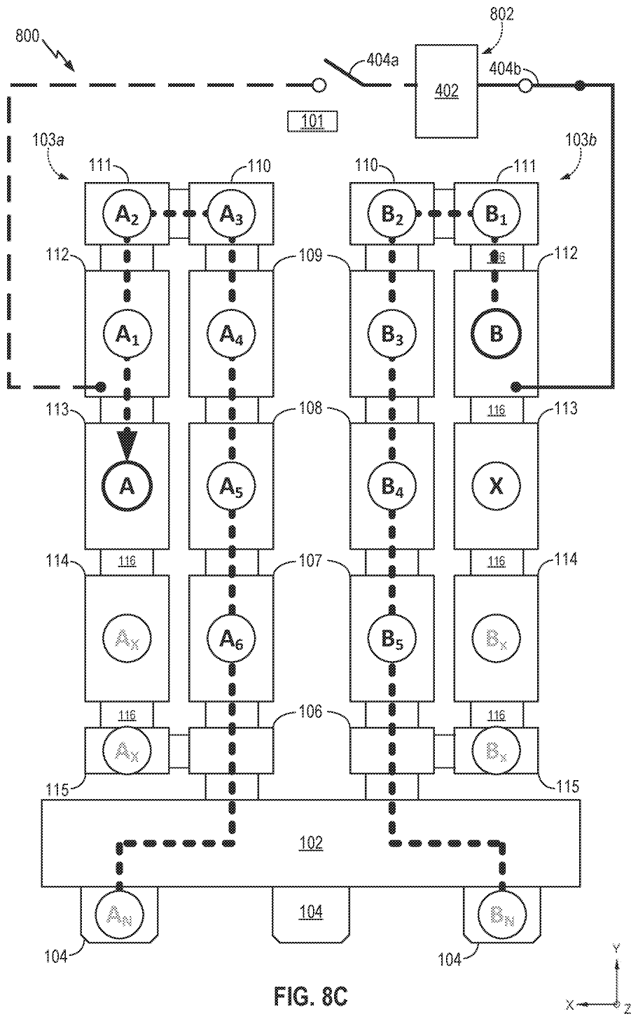

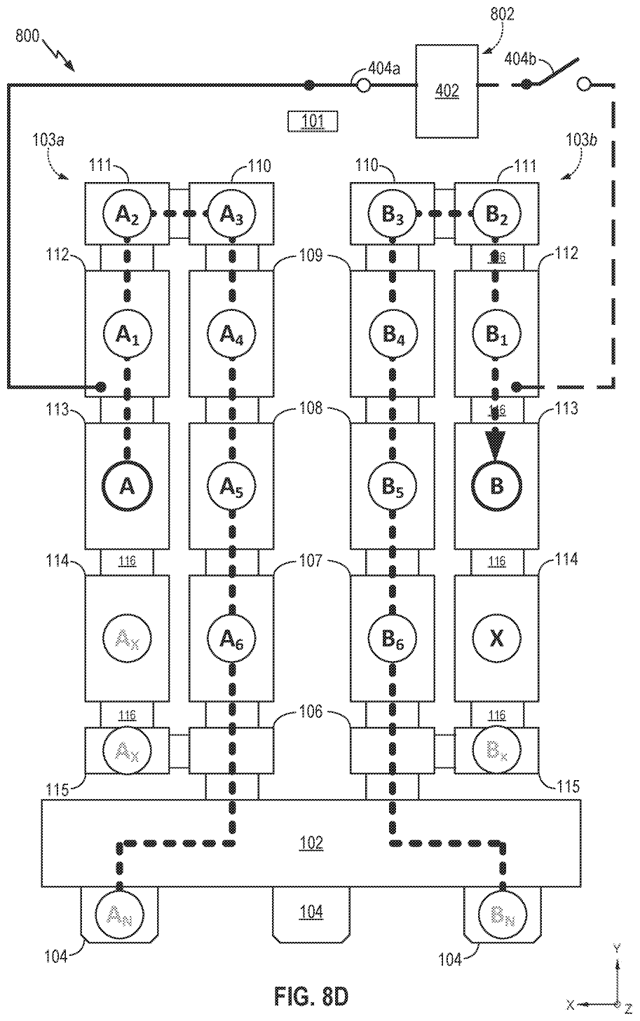

FIG. 7 is a flow diagram of a method 700 of sharing a resource, such as sharing a power supply, vacuum pump, gas source, or other useful resource, in a substrate processing system according to one embodiment. Method 700 may be best understood with reference to FIGS. 8A-8D. While the operations of method 700 are described in a linear manner in the flow diagram shown in FIG. 7. As implemented, the operations of method 700 may occur simultaneously, may overlap in time, and may be repeated individually, or as a whole. Further, while only two substrates, substrate A and substrate B, are focused on in this example of method 700 illustrated in FIGS. 8A through 8D, as implemented, a plurality of substrates will be simultaneously moving one-after-another through the substrate processing system 800 at any given time.

FIG. 8A is a schematic view of a substrate processing system 800 according to one embodiment prior to method 700. The substrate processing system 800 includes the second station 107, the third station 108, the fourth station 109, the seventh station 112, the eighth station 113, and the ninth station 114 of first processing line 103a. The substrate processing system 800 includes the second station 107, the third station 108, the fourth station 109, the seventh station 112, the eighth station 113, and the ninth station 114 of second processing line 103b. Substrate processing system 800 additionally includes a common resource 802 which is in communication with the seventh station 112 of first processing line 103a, and the seventh station 112b of second processing line 103b configured to deliver a resource to a component within of the seventh station 112 of first processing line 103a, and the seventh station 112 of second processing line 103b.

In this example, the common resource 802 is a common power resource 402 (e.g., a DC, AC or RF power supply) configured to deliver a power resource to the substrate processing region of the seventh station 112 of first processing line 103a, and the seventh station 112b of second processing line 103b. As indicated by the open load switch 404a, and “dotted square line”, no power resource is being currently delivered from the common power resource 402 to the processing area of the seventh station 112 of first processing line 103a. Likewise, as indicated by the open load switch 404b, and “dotted square line”, no power resource is being currently delivered from the common power resource 402 to the processing area of the seventh station 112 of second processing line 103b.

At operation 710 of method 700, shown in FIG. 8A, a first substrate “A”, initially having been received by a robot (not shown) from a front opening unified pod (FOUP) 104 of the factory interface 102, has, as indicated by the “rounded dot path”, transited to a carrier (not shown) in the first station 106 by the robot. Substrate A is then sequentially transferred from the first station 106 to the second station 107, the third station 108, and the fourth station 109, before being conveyed through the fifth station 110, conveyed through the sixth station 111, and then being positioned within the seventh station 112 of the first processing line 103a. The seventh station 112 of the first processing line 103a may be a tantalum nitride deposition station, copper deposition station, etching station, or any deposition station that deposits at least one layer on the substrate. The seventh station 112 of the first processing line 103a may utilize PVD, CVD, ALD, or other suitable process as required in the first processing line 103a.

During the sequential transferring process, one or more processing steps (e.g., non-deposition processes) may be performed on a substrate (i.e., substrates A₁, A₂, A₃, A₄, A₅, . . . , A_{N}) within each of the second station 107, the third station 108, and the fourth station 109, before being conveyed through the fifth station 110 and is currently positioned in the sixth station 111 of first processing line 103a.

Similarly, a second substrate “B”, initially having been received (not shown) from a FOUP 104 of the factory interface 102, has, as indicated by the “rounded dot path”, before being conveyed through the fifth station 110 and then being positioned within the sixth station 111 of the second processing line 103b.

During the sequential transferring process one or more processing steps (e.g., non-deposition processes) may be performed on a substrate (i.e., substrates B₁, B₂, B₃, B₄, . . . , B_{N}) within each of the second station 107, the third station 108, and the fourth station 109, before being conveyed through the fifth station 110 and then being positioned in the sixth station 111 as substrate “X” is currently positioned within the seventh station 112 of second processing line 103b. As indicted by the “solid line”, and closed load switch 404b, delivery of the power resource from the common power resource 402 to the processing area of the seventh station 112 of the second processing line 103b where substrate X is undergoing a deposition process, and thus the shared resource is providing power to a component within the seventh station 112 of the second processing line 103b.

When the processing within the seventh station 112 of the second processing line 103b is complete, and the chamber no longer requires the provided power from the common power resource (e.g., when substrate X has completed processing in the seventh station 112), several operations occur as illustrated in FIG. 8B. As noted above the operations of method 700 may occur simultaneously, may overlap in time, and may be repeated individually, or as a whole, as required.

For operation 720 of method 700, shown in FIG. 8B, the second substrate “B” is sequentially transferred into the processing area of the seventh station 112 of the second processing line 103b. The seventh station 112 of the second processing line 103b may be a tantalum nitride deposition station, copper deposition station, or any deposition station that deposits at least one layer on the substrate. The seventh station 112 of the second processing line 103b may utilize PVD, CVD, ALD, or other suitable process as needed in the second processing line 103b.

During the sequential transferring process of the second substrate B to the seventh station 112, other substrates are sequentially transferred in the second processing line 103b. Substrate X sequentially transfers to the eighth station 113. Substrate B₁ sequentially transfers to the sixth station 111. Substrate B₂ sequentially transfers to the fifth station 110. Substrate B₃ sequentially transfers to the fourth station 109. Substrate B₄ sequentially transfers to the third station 108. Substrate B₅ enters the second processing line 103b and sequentially transfers to the second station 107, and a substrate Bₓ leaves the second processing line 103b.

Additionally during the sequential transferring process of the plurality of substrates of the second processing line 103b, operation 730 of method 700, and operation 740 of method 700, shown in FIG. 8B, occur at approximately the same time. During operation 730 of method 700, load switch 404a closes for a first configurable period of time which allows delivery, as indicated by the “solid line”, of power from the common power resource 404 to the processing area of the seventh station 112 of the first processing line 103a to allow the deposition process on substrate A to be performed. Approximately at the same time, operation 730 of method 700 occurs, operation 740 of method 700, the power resource from the common power resource 402, as indicated by the open load switch 404b, and “dotted square line”, is locked out from the processing area of the seventh station 112 of the second processing line 103b for the first configurable period of time. As noted above, the second substrate B is loaded into the processing area of the seventh station 112 of the second processing line 103b, however substrate B is unable to being processing until the processing of substrate A, currently loaded in seventh station 112 of the first processing line 103a, is complete. If the processing time (e.g., the first configurable period of time) for substrate A exceeds the processing time of substrate B (e.g., a second configurable period of time), the throughput of the second processing line 103b will decrease. The overall throughput of the substrate processing system 800 may also decrease.

At, or about, the ending of the first configurable period of time, the processing area of the seventh station 112 of the first processing line 103a no longer requires the power provided from the common power resource (e.g., when the first configurable period of time has elapsed), several operations occur as illustrated in FIG. 8C.

In some embodiments, the difference in time (Δt) from when the first substrate A is loaded into the processing area of the seventh station 112 of the first processing line 103a and the time from when the second substrate B is loaded into the processing area of the seventh station 112 of the second substrate line 103b is less than the substrate processing time within the seventh station 112 of the first processing line 103a, or the time the shared resource is in use during the processing of the substrate within the seventh station 112 of the first processing line 103a (e.g., lockout period of time).

At operation 750 of method 700, shown in FIG. 8C, load switch 404b closes for a second configurable period of time which allows delivery, as indicted by the “solid line”, of the power resource from the common power resource 404 to the processing area of the seventh station 112 of the second processing line 103b beginning the deposition process of substrate B. About the same time, operation 750 of method 700 takes place, at operation 760 of method 700, the power resource from the common power resource 402, as indicated by the open load switch 404a, and “dotted square line”, is locked out from the processing area of the seventh station 112 of the first processing line 103a for the second configurable period of time.

Additionally shown in FIG. 8C, after the deposition steps are completed at the seventh station 112 of the first processing line 103a, operation 770 of method 700 begins. At operation 770 of method 700, the first substrate A is sequentially transferred from the processing area of the seventh station 112 of the first processing line 103a to the eighth station 113 of the first processing line 103a.

Also shown in FIG. 8C, during operation 770 of method 700, other substrates are sequentially transferred in the first processing line 103a. Substrate A₁ sequentially transfers to the seventh station 112. Substrate A₂ sequentially transfers to the sixth station 111. Substrate A₃ sequentially transfers to the fifth station 110. Substrate A₄ sequentially transfers to the fourth station 109. Substrate A₅ sequentially transfers to the third station 108. Substrate A₆ enters the first processing line 103a and sequentially transfers to the second station 107, and a substrate Aₓ leaves the first processing line 103a. As noted above, the substrate A₁ is loaded into the processing area of the seventh station 112 of the first processing line 103a, however substrate A₁ is unable to being processing until the processing of substrate B, currently loaded in seventh station 112 of the second processing line 103b, is complete. If the processing time (e.g., the second configurable period of time) for substrate B exceeds the processing time of substrate A₁ (e.g., the first configurable period of time), the throughput of the second processing line 103b will decrease. The overall throughput of the substrate processing system 800 may also decrease.

As shown in FIG. 8D, at, or about, the ending of the second configurable period of time, when the deposition steps are completed at the seventh station 112 of the second processing line 103b, operations 730 and 740 repeat. About the same time as operations 730 740, and 770 occur, operation 780 begins. At operation 780 of method 700, shown in FIG. 8D, the first substrate B is sequentially transferred from the processing area of the seventh station 112, to the eighth station 113 of the second processing line 103b.

Also shown in FIG. 8D, during operation 780 of method 700, other substrates are sequentially transferred in the second processing line 103b. Substrate B₁ sequentially transfers to the seventh station 112. Substrate B₂ sequentially transfers to the sixth station 111. Substrate B₃ sequentially transfers to the fifth station 110. Substrate B₄ sequentially transfers to the fourth station 109. Substrate B₅ sequentially transfers to the third station 108. Substrate B₆ enters the second processing line 103b and sequentially transfers to the second station 107, and a substrate Bₓ leaves the second processing line 103b.

As noted above the operations of method 700 may occur simultaneously, may overlap in time, and may be repeated individually, or as a whole, as required as the plurality of substrates (i.e., substrates A, A₁, A₂, . . . , A_{N}, and B, B₁, B₂, . . . , B_{N}, and X), and simultaneously move one-after-another through the substrate processing system 800 at any given time.

As noted above, the sequence of operations disclosed in method 700 can also be performed using other types of shared resources disclosed herein. In one example, instead of providing power to one or more components within the seventh station 112 within each of the processing lines 130a, 103b, the shared resource could instead be a rough pump and the open load switches could be vacuum compatible valves that are used evacuate the processing region of the seventh stations during non-overlapping or minimally overlapping periods of time. In another example, instead of providing power to one or more components within the seventh station 112 within each of the processing lines 130a, 103b, the shared resource could instead be a gas and the open load switches could be gas compatible valves that are used to provide a gas to achieve an gas pressure greater than about 760 Torr within the processing region of the seventh stations during non-overlapping or minimally overlapping periods of time. In another example, instead of providing power to one or more components within the seventh station 112 within each of the processing lines 130a, 103b, the shared resource could instead be a heat exchange medium and the open load switches could be compatible valves that are used to provide the heat exchange medium to provide a heat exchanging and heat control system within the processing region of the seventh stations during non-overlapping or minimally overlapping periods of time. In further examples, the shared resource could be any combination of the forgoing resources.

### ADDITIONAL CONSIDERATIONS

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A method of substrate processing, comprising:
processing a first substrate within a first station within a first substrate processing line of a substrate processing system, wherein
the first substrate processing line comprises a plurality of stations that comprise at least the first station, and
processing the first substrate comprises:
loading the first substrate into a processing area of the first station of the first substrate processing line, and
delivering a first resource from a first common resource to a component within the first station of the first substrate processing line for a first configurable period of time;
locking out the first resource from providing the first common resource to a component within a first station of a second substrate processing line for the first configurable period of time;
unloading the first substrate from the processing area of the first station of the first substrate processing line after the first configurable period of time has elapsed;
processing a second substrate within the first station within the second substrate processing line of the substrate processing system, wherein
the second substrate processing line comprises a plurality of stations that comprise at least the first station, and
processing the second substrate comprises:
loading the second substrate into a processing area of the first station of the second substrate processing line, and
delivering the first resource from the first common resource to the component within the first station of the second substrate processing line for a second configurable period of time;
locking out the first resource from providing the first common resource to the component within the first station of the first substrate processing line for the second configurable period of time; and
unloading the second substrate from the processing area of the first station of the second substrate processing line.

2. The method of claim 1, wherein loading the second substrate into the processing area of the first station of the second substrate processing line occurs before the first configurable period of time has elapsed.

3. The method of claim 1, further comprising:
processing a third substrate within a second station within a first substrate processing line of a substrate processing system, wherein
the first substrate processing line comprises a plurality of stations that comprise at least the first station, and at least the second station, and
processing the third substrate comprises:
loading the third substrate into a processing area of the second station of the first substrate processing line, wherein loading the third substrate into the processing area of the second station occurs before the second configurable period of time has elapsed, and
delivering a second resource from a second common resource to a component within the second station of the first substrate processing line for a third configurable period of time;
locking out the second resource from providing the second common resource to a component within a second station of the second substrate processing line for the third configurable period of time;
unloading the third substrate from the processing area of the second station of the first substrate processing line after the third configurable period of time has elapsed;
processing a fourth substrate within a second station within the second substrate processing line of the substrate processing system, wherein
processing the fourth substrate comprises:
loading the fourth substrate into a processing area of the second station of the second substrate processing line, wherein loading the fourth substrate into the processing area of the second station of the second substrate processing line occurs before the third configurable period of time has elapsed, and
delivering a second resource from the second common resource to the component within the second station of the second substrate processing line for a fourth configurable period of time;
locking out the second resource from providing the second common resource to the component within the second station of the first substrate processing line for the fourth configurable period of time; and
unloading the fourth substrate from the processing area of the second station of the second substrate processing line.

4. The method of claim 3, wherein the first common resource, and the second common resource are the same type of common resource, wherein the common resource is selected from a group consisting of a power resource, a gas resource, or a vacuum resource.

5. The method of claim 1, wherein a difference in time from when the first substrate is loaded into the processing area of the first station of the first substrate processing line and the time from when the first substrate is loaded into the processing area of the first station of the second substrate processing line is less than the first configurable period of time.

6. The method of claim 1, wherein the first resource from the first common resource further comprises:
a power resource from a common power resource,
a gas resource from a common gas resource,
a vacuum resource from the common gas resource,
or combination thereof.

7. The method of claim 1, wherein the loading of the first substrate, and the unloading of the first substrate, from first station of the plurality of stations of the first substrate processing line further comprises:
transporting the first substrate between the plurality of stations by use of a magnetic transportation system.

8. The method of claim 1, wherein the loading of the second substrate, and the unloading of the second substrate, from first station of the plurality of stations of the second substrate processing line further comprises:
transporting the second substrate between the plurality of stations by use of a magnetic transportation system.

9. A method of substrate processing, comprising:
processing a first substrate within a first station within a first substrate processing line of a substrate processing system, wherein
the first substrate processing line comprises a plurality of stations that comprise at least the first station, and
processing the first substrate comprises:
loading the first substrate into a processing area of the first station of the first substrate processing line, wherein loading the first substrate into the processing area of the first station of the first substrate processing line occurs before a third configurable period of time, and a fourth configurable period of time, have elapsed,
delivering a first resource from a first common resource to a component within the first station of the first substrate processing line for a first configurable period of time, wherein the first resource from the first common resource is a power resource from a common power resource, and
delivering a second resource from a second common resource to a component within the first station of the first substrate processing line for a second configurable period of time, wherein the second resource from the second common resource is a vacuum resource from a common vacuum resource;
locking out the first resource from providing the first common resource to a component within a first station of a second substrate processing line for the first configurable period of time;
locking out the second resource from providing the second common resource to a component within a first station of a second substrate processing line for the second configurable period of time;
unloading the first substrate from the processing area of the first station of the first substrate processing line after the first configurable period of time, and the second configurable period of time, have elapsed;
processing a second substrate within the first station within the second substrate processing line of the substrate processing system, wherein
the second substrate processing line comprises a plurality of stations that comprise at least the first station, and
processing the second substrate comprises:
loading the second substrate into a processing area of the first station of the second substrate processing line, wherein loading the second substrate into the processing area of the first station of the second substrate processing line occurs before the first configurable period of time, and the second configurable period of time, have elapsed,
delivering the first resource from the first common resource to the component within the first station of the second substrate processing line for the third configurable period of time, and
delivering the second resource from the second common resource to the component within the first station of the second substrate processing line for the fourth configurable period of time;
locking out the first resource from providing the first common resource to the component within the first station of the first substrate processing line for the third configurable period of time;
locking out the second resource from providing the second common resource to the component within the first station of the first substrate processing line for the fourth configurable period of time; and
unloading the second substrate from the processing area of the first station of the second substrate processing line after the third configurable period of time, and the fourth configurable period of time, have elapsed.

10. The method of claim 9, wherein the first resource from the first common resource further comprises:
a power resource from a common power resource,
a gas resource from a common gas resource,
a vacuum resource from the common gas resource,
or combination thereof.

11. The method of claim 9, wherein the second resource from the second common resource further comprises:
a power resource from a common power resource,
a gas resource from a common gas resource,
a vacuum resource from the common gas resource,
or combination thereof.

12. The method of claim 9, wherein a difference in time from when the first substrate is loaded into the processing area of the first station of the first substrate processing line and the time from when the first substrate is loaded into the processing area of the first station of the second substrate processing line is less than the first configurable period of time.

13. The method of claim 9, wherein the loading of the first substrate, and the unloading of the first substrate, from first station of the plurality of stations of the first substrate processing line further comprises:
transporting the first substrate between the plurality of stations with a magnetic transportation system.

14. The method of claim 9, wherein the loading of the second substrate, and the unloading of the second substrate, from first station of the plurality of stations of the second substrate processing line further comprises:
transporting the second substrate between the plurality of stations with a magnetic transportation system.
